(19) United States
(12) Patent Application Publication
(10) Pub. No.: US 2003/0227761 A1
(43) Pub. Date: Dec. 11, 2003

(54) Expansion card retention mechanism

(76) Inventors: Hung-Ta Liao, Taipei (TW); Ching-Yuan Wang, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/164,143

(22) Filed: Jun. 5, 2002

(51) Int. Cl. G06F 1/16; H05K 5/00; H05K 7/00; H05K 7/14; H05K 7/18

(52) U.S. Cl. 361/801; 361/684

(57) ABSTRACT

The desired results are advantageously achieved by providing an expansion card retention mechanism used for retaining an expansion card in a computer system, wherein the expansion card retention mechanism comprises a latch connected to a main body of the computer system by a hinge at a bottom of the latch. The latch further comprises a prominence at a top of the latch. While the prominence is pushed and the latch is opened, the expansion card can be released and while the latch is rotated toward the expansion card and the prominence is engaged in a notch at the main body of the computer system, the expansion card is retained. The latch is preferably made of a plastic material and in a shape similar to a question mark “?”.

### BACKGROUND OF THE INVENTION

1. Field of the Invention

The invention relates in general to an expansion card retention mechanism, and more particularly to an expansion card retention mechanism including a latch.

2. Description of the Related Art

Microprocessor based computer systems typically require or include facilities for connecting one or more expansion cards to the system. Expansion cards extend the capabilities of computer systems by providing dedicated hardware to achieve a variety of tasks. Graphics adapters, high-speed network controllers, sound cards, and modem cards are among some of the more common types of expansion cards.

Typically, expansion cards are interfaced to the microprocessor by physically inserting the expansion card into an expansion card connector. In many cases, the expansion card includes facilities for making an external connection to the expansion card. The expansion card must be maintained in a precise position to ensure reliable operation. Those familiar with expansion cards and expansion cards connectors will appreciate the ease with which a slight displacement or movement of the expansion card can result in a faulty connection. Thus, maintaining precise positioning of expansion cards is an important issue in the design and manufacturing of computer systems. Historically, the secure positioning of expansion cards was maintained by screwing each expansion card into place with one or more securing screws. Unfortunately, the use of screws to secure expansion boards undesirably increases the amount of time and effort required to install, remove, replace, and otherwise service the expansion cards in a system.

There were some other inventions using other mechanisms other than screws to position the expansion cards. Unfortunately, these inventions typically require highly intricate clips, hinges, or bracket structures that introduce an undesirably expensive piece of hardware to the system component list. It would be highly desirable to introduce an easily manufactured and inexpensive expansion card retention mechanism that overcomes the limitations of the prior art.

### SUMMARY OF THE INVENTION

The desired results are advantageously achieved by providing an expansion card retention mechanism used for retaining an expansion card in a computer system, wherein the expansion card retention mechanism comprises a latch connected to a main body of the computer system by a hinge at a bottom of the latch. The latch further comprises a prominence at a top of the latch. While the prominence is pushed and the latch is opened, the expansion card can be released and while the latch is rotated toward the expansion card and the prominence is engaged in a notch at the main body of the computer system, the expansion card is retained. The latch is preferably made of a plastic material and in a shape similar to a question mark “?”.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIGS. 1A˜1B shows the operation of the expansion card retention mechanism according to a preferred embodiment of the invention.

FIG. 2 shows the detailed structure of the latch according to a preferred embodiment of the invention.

### DETAILED DESCRIPTION OF THE INVENTION

In the following description, for purposes of explanation, specific numbers, materials and configurations are set forth in order to provide a thorough understanding of the present invention. However, it will be apparent to one skilled in the art that the present invention may be practiced without the specific details. In other instances, well-known features are omitted or simplified in order not to obscure the present invention.

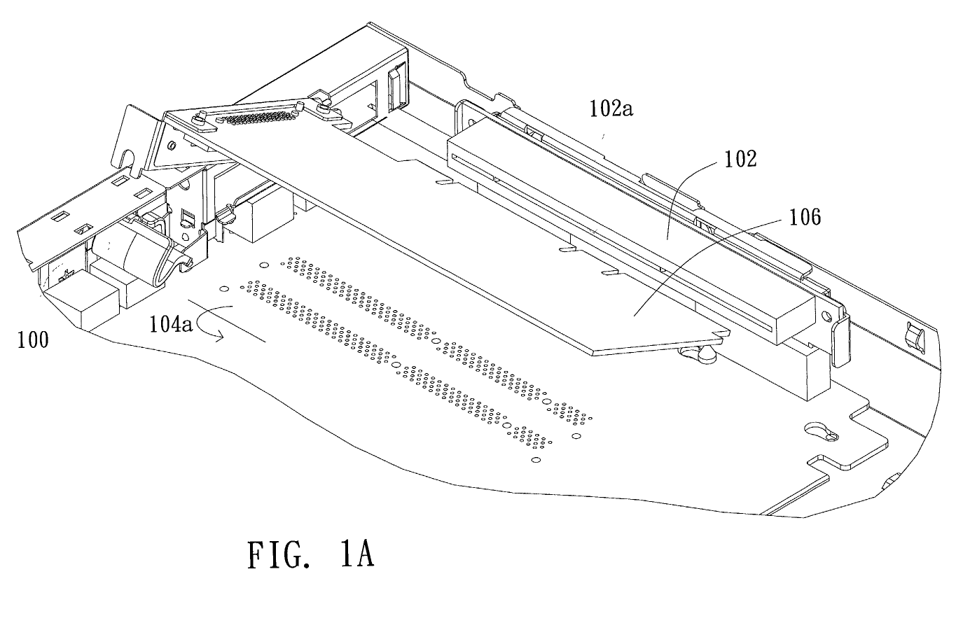

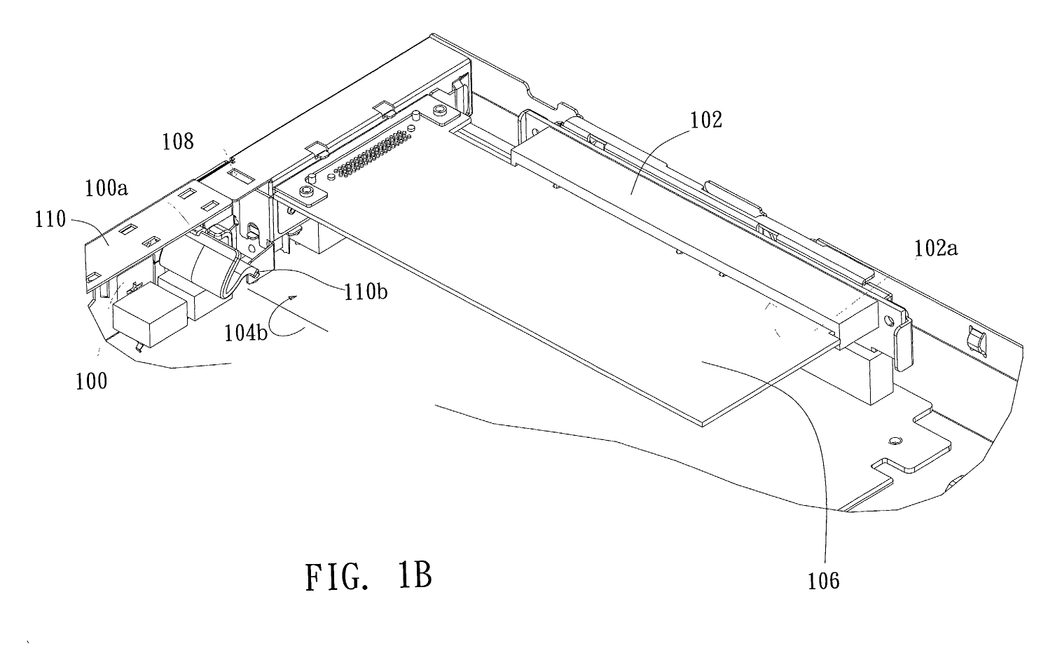

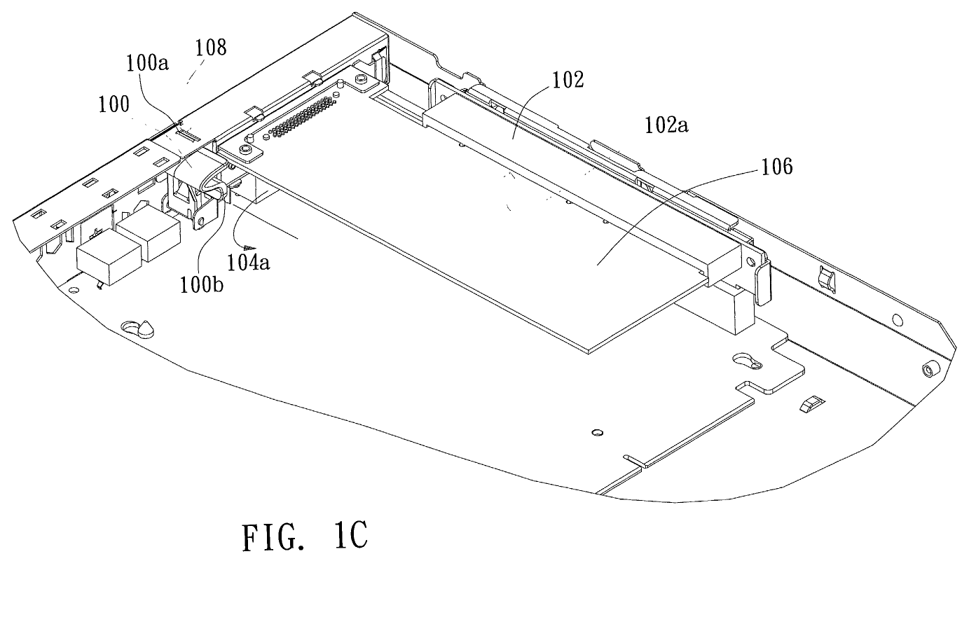

Referring to FIG. 1A, while the expansion card 106 is released from the expansion card connector 102, the latch 100 is opened. That is, the latch 100 rotates in a direction away from the expansion card connector 102, as indicated by the arrow 104a. While the latch 100 is opened, the expansion card 106 is able to insert into the slot 102 of the connector 102. Then, as shown in FIG. 1B, while the expansion card 106 is inserted into the slot 102a of the connector 102 and properly positioned, the latch 100 can be rotated manually as indicated by the arrow 104b. The latch 100 is connected to the main body 110 of the microprocessor based computer systems, such as a personal computer or a server, by a hinge 100b at the bottom of the latch 100, so that the latch 100 can rotate around the hinge 100b. The latch 100 further includes a prominence 100a at the top. While the latch 100 is rotated as indicated by the arrow 104b and the prominence 100a is engaged in the notch 108, the latch 100 is closed. Consequently, the latch 100 restricts the movement of the expansion card 106.

As shown in FIG. 1C, while the expansion card 106 is desired to be removed, the latch 100 can be manually rotated in a direction away from the expansion card 106, as indicated by the arrow 104a, by pushing the prominence 100a downwardly to release the prominence 100a from the notch 108. As a result, the latch 100 is loose so that expansion card 106 can be easily removed from the slot 102a of the connector 102.

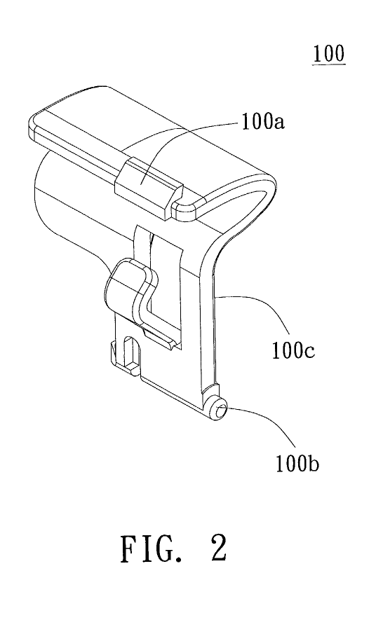

FIG. 2 shows the detailed structure of the latch 100. The latch 100 includes a main body 100c, which is preferably in a shape similar to a question mark “?” but not limited thereto. Any other shape able to be shortened in total length, while the prominence 100a is pushed, is applicable. A prominence 100a at the top and a hinge 100b at the bottom are two other main compartments of the latch 100. The latch 100 is preferably made of a plastic material so that the latch 100 has a plastic deformation and the prominence 100a can be loose from the notch 108, while the prominence 100a is pushed.

It will be apparent to those skilled in the art having the benefit of this disclosure that the present invention contemplates securing and retaining expansion cards of a computer system in their respective expansion card connectors with a minimum of fastening hardware. The advantages of the expansion card retention mechanism further includes:

1. Not any screw is used to secure expansion boards. Thus, the amount of time and effort required to install, remove, and replace the expansion cards in a system is dramatically reduced.

2. An easily manufactured and inexpensive expansion card retention mechanism that overcomes the limitations of the prior art is introduced.

It is understood that the form of the invention shown and described in the detailed description and the drawings are to be taken merely as presently preferred examples. All the variations of the preferred embodiments disclosed, including using the same retention mechanism to secure and retain any other added-on card, are within the scope of the invention.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An expansion card retention mechanism used for retaining an expansion card in a computer system, wherein the expansion card retention mechanism comprises:
a latch connected to a main body of the computer system, wherein the latch comprises:
a hinge at a bottom of the latch for connecting the main body of the computer system and the latch; and
a prominence at a top of the latch, wherein the expansion card is released, while the prominence is pushed to let the latch be opened, and wherein the expansion card is retained, while the latch is closed.

2. The expansion card retention mechanism as claimed in claim 1, further comprises a connector, set on the main body of the computer system, with a slot for the expansion card to insert in.

3. The expansion card retention mechanism as claimed in claim 1, wherein the latch is in a shape similar to a question mark “?”.

4. The expansion card retention mechanism as claimed in claim 1, wherein the latch is made of a plastic material so that the latch has a plastic deformation.

5. The expansion card retention mechanism as claimed in claim 1, wherein the prominence is loose from a notch at the main body of the computer system, while the prominence is pushed.

6. The expansion card retention mechanism as claimed in claim 5, wherein the prominence is engaged in the notch, while the latch is closed.

7. The expansion card retention mechanism as claimed in claim 1, wherein the computer system is a personal computer.

8. The expansion card retention mechanism as claimed in claim 1, wherein the computer system is a server.

9. An added-on card retention mechanism for retaining an added-on card in a computer system, wherein the added-on card retention mechanism comprises:
a latch connected to a main body of the computer system by a hinge at a bottom of the latch, wherein the latch further comprises:
a prominence at a top of the latch, wherein the added-on card can be released and the latch is opened, while the prominence is pushed, and wherein the added-on card is retained, while the latch is rotated toward the added-on card and the prominence is engaged in a notch at the main body of the computer system.

10. The added-on card retention mechanism as claimed in claim 7, wherein the computer system further comprises a connector with a slot for the added-on card to insert in.

11. The added-on card retention mechanism as claimed in claim 7, wherein the latch is in a shape similar to a question mark “?”.

12. The added-on card retention mechanism as claimed in claim 7, wherein the latch is made of a plastic material so that the latch has a plastic deformation.

13. The added-on card retention mechanism as claimed in claim 7, wherein the prominence is loose from the notch, while the prominence is pushed.

14. The added-on card retention mechanism as claimed in claim 7, wherein the computer system is a personal computer.

15. The added-on card retention mechanism as claimed in claim 7, wherein the computer system is a server.
